(19) United States
(12) Patent Application Publication
(10) Pub. No.: US 2022/0206704 A1
(43) Pub. Date: Jun. 30, 2022

(54) EMBEDDED MEMORY SYSTEM AND MEMORY TESTING METHOD

(71) Applicant: REALTEK SEMICONDUCTOR CORPORATION, Hsinchu (TW)

(72) Inventor: YEN-PIN CHEN, Hsinchu (TW)

(21) Appl. No.: 17/512,707

(22) Filed: Oct. 28, 2021

(30) Foreign Application Priority Data
Dec. 31, 2020 (TW) 109147159

(51) Int. Cl. G06F 3/06

(52) U.S. Cl. CPC G06F 3/0653; G06F 3/0679; G06F 3/0604; G06F 3/0632

(57) ABSTRACT

An embedded memory system includes an embedded memory circuit and a host circuit. The embedded memory circuit is configured to store a lookup table. The host circuit is configured to utilize a testing clock signal having phases and instructions in a program of the embedded memory circuit to run a test on the embedded memory circuit, and record a corresponding relation between each of the plurality of instructions and the plurality of phases, in order to generate the lookup table.

### BACKGROUND OF THE DISCLOSURE

### 1. Field of the Disclosure

The present disclosure relates to an embedded memory system. More particularly, the present disclosure relates to an embedded memory system that utilizes a boot loader to run a timing scan test and a memory testing method.

### 2. Description of Related Art

In existing approaches, predefined signal patterns or extra test programs are employed to test timings of a memory circuit. However, the predefined signal patterns are not actual data written or read by the memory circuit in subsequent applications, and the test programs are not actual programs executed by the memory circuit in subsequent applications. The timing test results generated in response to these signal patterns or the test programs may be not suitable to set actual operations of the memory circuit. In other words, the timing scan range obtained by the existing approaches may be different from the actual timing range used by the memory circuit. As a result, the memory circuit may not utilize the proper timing in actual applications.

### SUMMARY

In some aspects of the present disclosure, an embedded memory system includes an embedded memory circuit and a host circuit. The embedded memory circuit is configured to store a lookup table. The host circuit is configured to utilize a testing clock signal having a plurality of phases and a plurality of instructions in a program of the embedded memory circuit to run a test on the embedded memory circuit, and record a corresponding relation between each of the plurality of instructions and the plurality of phases, in order to generate the lookup table.

In some aspects of the present disclosure, a memory testing method includes the following operations: utilizing a testing clock signal having a plurality of phases and a plurality of instructions in a program to run a test on an embedded memory circuit; and recording a corresponding relation between each of the plurality of instructions and the plurality of phases, in order to generate a lookup table, in which the embedded memory circuit is configured to select a specific phase, which corresponds to a first instruction in the plurality of instructions, in the plurality of phases according to the lookup table, in order to execute the first instruction.

These and other objectives of the present disclosure will be described in detailed description with various figures and drawings.

### BRIEF DESCRIPTION OF THE DRAWINGS

FIG. 1 is a schematic diagram of an embedded memory system according to some embodiments of the present disclosure.

FIG. 2 is a flow chart of a timing scan testing method according to some embodiments of the present disclosure.

FIG. 3 is a flow chart of a memory testing method according to some embodiments of the present disclosure.

FIG. 4 is a schematic diagram of a result of the timing scan test according to some embodiments of the present disclosure.

### DETAILED DESCRIPTION

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may indicate a system formed with one or more circuits. The term “circuit” may indicate an object, which is formed with one or more transistors and/or one or more active/passive elements based on a specific arrangement, for processing signals.

As used herein, the term “and/or” includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, like elements in various figures are designated with the same reference number.

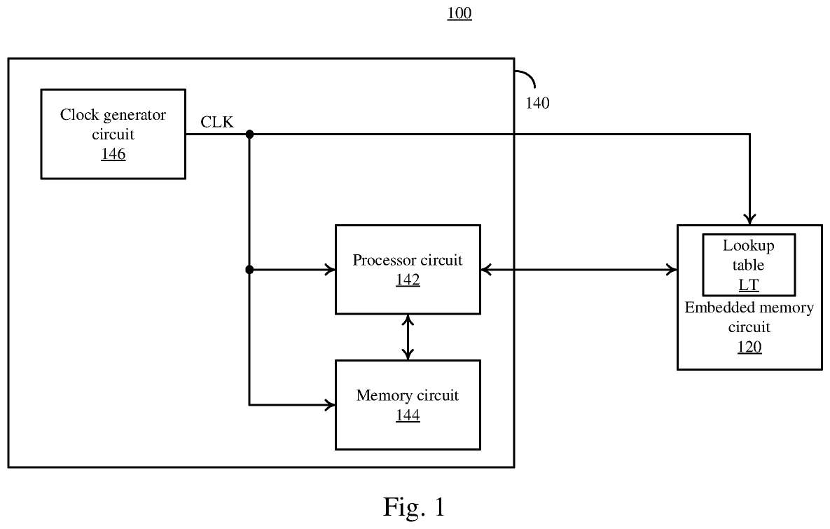

FIG. 1 is a schematic diagram of an embedded memory system 100 according to some embodiments of the present disclosure. The embedded memory system 100 includes an embedded memory circuit 120 and a host circuit 140. In some embodiments, the embedded memory circuit 120 may be (but not limited to) an embedded multimedia card (eMMC) chip, which includes a memory array (not shown) for storing data and a controller circuit (not shown) for controlling the memory array. In some embodiments, the memory array may be a flash memory.

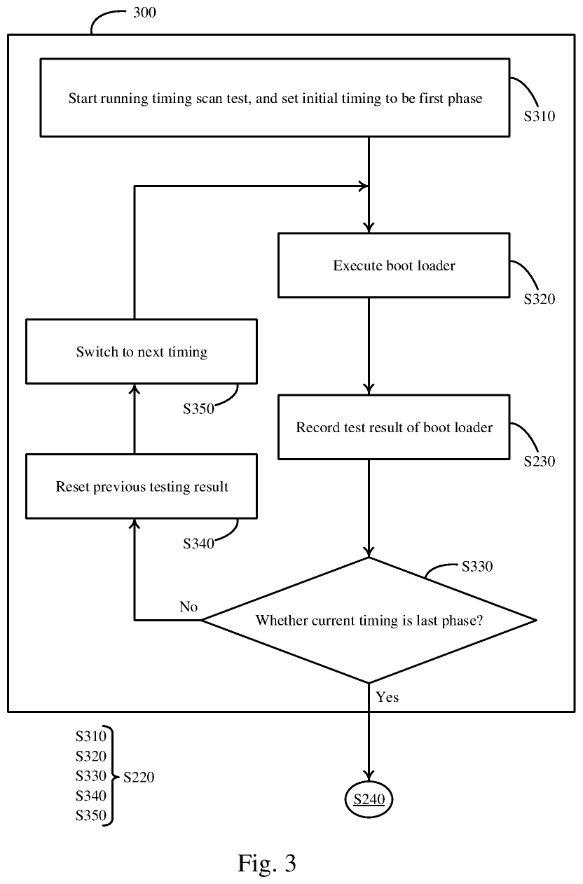

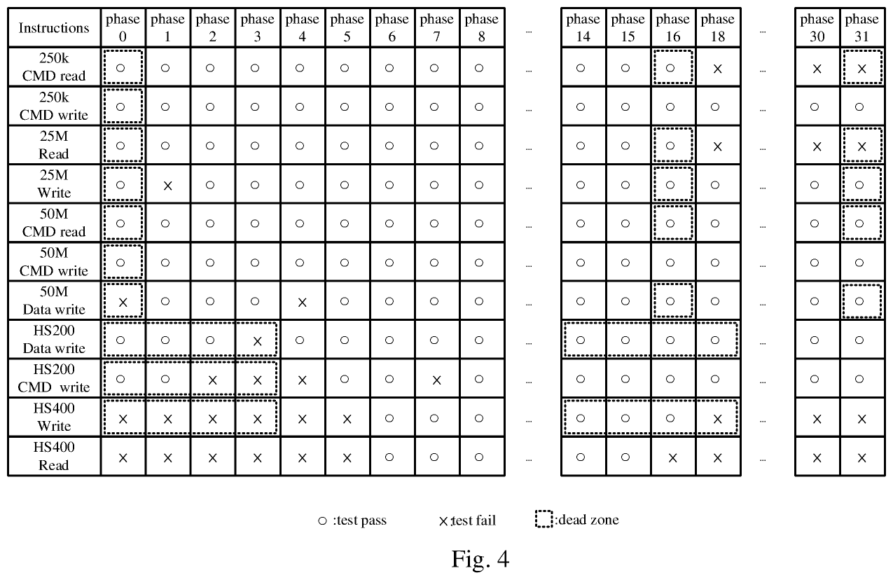

In some embodiments, the host circuit 140 may be configured to run a timing scan test on the embedded memory circuit 120, in order to generate a lookup table LT. In some embodiments, the host circuit 140 includes a processor circuit 142, a memory circuit 144, and a clock generator circuit 146. The processor circuit 142 may be configured to perform operations in FIG. 3, in order to run the timing scan test on the embedded memory circuit 120 to generate the lookup table LT. The memory circuit 144 may be configured to temporarily store results of the timing scan test, and output these results to be the lookup table LT after the timing scan test is completed. The clock generator circuit 146 is configured to generate a testing clock signal CLK and transmit the same to the embedded memory circuit 120, and the embedded memory circuit 120 may utilize the testing clock signal CLK to execute instructions (e.g., read/write instructions, etc., in FIG. 4) in a program, in order to run the timing scan test.

In some embodiments, the testing clock signal CLK has multiple phases (e.g., phases 0-31 in FIG. 4), and the lookup table LT is configured to store corresponding relations between each instruction and the phases. In some embodiments, after the timing scan test is completed, the host circuit 140 may store the lookup table LT to the embedded memory circuit 120. As a result, the embedded memory circuit 120 may select a clock signal having a proper phase according to the lookup table LT, in order to execute the corresponding instruction. In some embodiments, the above program may be a boot loader, and the boot loader is a kernel that operates with the embedded memory circuit 120 or is a program that is executed during a boot process of an operating system. In other words, the host circuit 140 utilizes the program which is actually executed by the embedded memory circuit 120 to run the timing scan test on the embedded memory circuit 120. Compared with test results obtained by using an additional test program (or an addition test signal), the test results obtained by using the boot loader can be more accurate. As a result, the embedded memory circuit 120 is able to utilize the lookup table LT to select the proper phase to execute the corresponding instruction.

In some embodiments, the host circuit 140 may be an application-specific integrated circuit. In some embodiments, the processor circuit 142 may be (but not limited to) a central processing unit (CPU), a multi-processor, a pipeline processor, a distributed processing system, and so on. In some embodiments, the memory circuit 144 may be (but not limited to) an non-transitory computer readable storage medium. In some embodiments, the non-transitory computer readable storage medium may be an electrical, magnetic, optical, infrared and/or semiconductor device. For example, the non-transitory computer readable storage medium includes(but not limited to) a semiconductor or solid state memory, a magnetic tape, a removable computer diskette, a random access memory (RAM), a read only memory (ROM), a hard disk and/or an optical disc. The about types of the processor circuit 142 and the memory circuit 144 are given for illustrative purposes, and the present disclosure is not limited thereto.

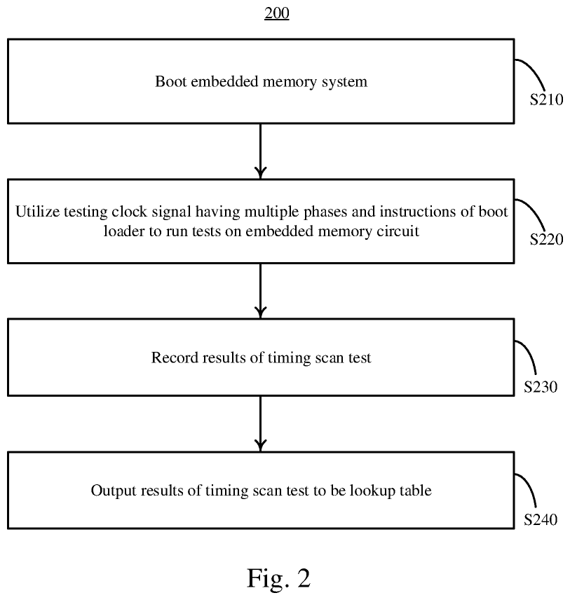

FIG. 2 is a flow chart of a timing scan testing method 200 according to some embodiments of the present disclosure. In some embodiments, the timing scan testing method 200 may be performed by (but not limited to) the embedded memory system 100 in FIG. 1.

In operation S210, an embedded memory system (e.g., the embedded memory system 100) is booted. In operation S220, a testing clock signal having multiple phases and multiple instructions of a boot loader are utilized to run test(s) on an embedded memory circuit. For example, the host circuit 140 may perform operations in FIG. 3, in order to test the embedded memory circuit 120. In operation S230, results of the timing scan test are recorded. For example, the processor circuit 142 may temporarily store the results of the timing scan test (as shown in FIG. 4) to the memory circuit 144 in FIG. 1. In operation S240, the results of the timing scan test are outputted to be a lookup table. For example, when the timing scan test is completed, the processor circuit 142 may output the test results stored in the memory circuit 144 to be the lookup table LT, and write the lookup table LT to the embedded memory circuit 120.

FIG. 3 is a flow chart of a memory testing method 300 according to some embodiments of the present disclosure. In some embodiments, operations S310, S320, S330, S340, and S350 can be considered as specific steps of operation S220 in FIG. 2. In operation S310, the timing scan test is started running, and an initial timing is set to be a first phase (e.g., phase 0 in FIG. 4). In operation S320, a boot loader is executed. In operation S230, test results of executing the boot loader are recorded. In operation S330, whether the current timing is a last phase (e.g., phase 31 in FIG. 4) is determined. If the current timing is the last phase, operation S240 in FIG. 2 is performed. Alternatively, if the current timing is not the last phase, operation S340 is performed. In operation S340, the previous test results are reset. In operation S350, the timing is switched to a next timing (e.g., switched from phase 0 to phase 1 in FIG. 4), and operation S320 is performed again.

FIG. 4 is a schematic diagram of a result of the timing scan test according to some embodiments of the present disclosure. In some embodiments, the boot loader includes write and/or read instructions that are performed with different clock frequencies. For example, as shown in FIG. 4, the boot loader may include (but not limited to) a command (labeled as “CMD”) read instruction performed with a clock signal having a frequency of 250 kHz (labeled as 250 k) (hereinafter referred as “first command read instruction” for simplicity), a command write instruction performed with a clock signal having a frequency of 250 kHz, a read instruction performed with a clock signal having a frequency of 25 MHz (labeled as 25M), a write instruction performed with a clock signal having the frequency of 25 MHz, a command read instruction performed with a clock signal having a frequency of 50 MHz, a command write instruction performed with the clock signal having the frequency of 50 MHz, a data write instruction performed with the clock signal having the frequency of 50 MHz, a data write instruction performed in a HS200 mode, a command write instruction performed in the HS200 mode, a command write instruction performed in a HS400 mode, and a read instruction performed in the HS400 mode.

In this example, the testing clock signal CLK in FIG. 4 has 32 phases (i.e., phase 0 to phase 31). At first, the host circuit 140 sets the phase of the testing clock signal CLK to be phase 0, and controls the embedded memory circuit 120 to sequentially executes the instructions of the boot loader (i.e., operation S310). The embedded memory circuit 120 utilizes the testing clock signal CLK having phase 0 to sequentially execute those instructions, and generates the corresponding test result.

For example, the embedded memory circuit 120 utilizes the testing clock signal CLK having phase 0 and the frequency of 250 kHz to execute the first command read instruction. If the first command read instruction can be executed properly (labeled as ∘), the embedded memory circuit 120 is able to read predetermined data (i.e., the read data is a predetermined value). Alternatively, if this read command cannot be properly executed (labeled as x), data read by the embedded memory circuit 120 is not the predetermined data (i.e., the read data is not the predetermined value). Therefore, the processor circuit 142 may determine whether the embedded memory circuit 120 utilizes the testing clock signal CLK having phase 0 to execute the first command read instruction properly according to the test result (i.e., whether the read data is the predetermined value) corresponding to the first command read instruction. With this analogy, the embedded memory circuit 120 may utilize the testing clock signal CLK having phase 0 and a corresponding frequency to sequentially execute the instructions, and the processor circuit 142 may determine whether the embedded memory circuit 120 utilizes the testing clock signal CLK having phase 0 to perform these instructions properly according to the test results corresponding to these instructions. For example, as shown in FIG. 4, the processor circuit 142 obtains that the embedded memory circuit 120 cannot utilize the testing clock signal CLK having phase 0 to properly execute the write instruction and the read instruction in the HS400 mode.

After testing results corresponding to all instructions are obtained (i.e., operation S230), the host circuit 140 may reset the embedded memory circuit 120 (i.e., operation S340) and switch the phase of the testing clock signal CLK from phase 0 to phase 1 (i.e., operation S350), in order to control the embedded memory circuit 120 to sequentially execute the instructions of the boot loader again (i.e., operation S320). The embedded memory circuit 120 utilizes the testing clock signal CLK having phase 1 to sequentially execute the instructions, and generates the corresponding testing results. With this analogy, the processor circuit 142 may obtain the corresponding relation between each instruction and phases 0-31 (as shown in FIG. 4). In some embodiments, the test results shown in FIG. 4 may be stored in the memory circuit 144. In some embodiments, according to the test results in FIG. 4, the host circuit 140 may determine that the embedded memory circuit 120 is able to properly execute the first command read instruction according to at least one first phase (e.g., phase 0 to phase 16) in phases 0-31.

After the corresponding relation between each instruction and phases 0-31 are obtained, the processor circuit 142 may generate the lookup table LT. In some embodiments, the lookup table LT may be expressed as the following table 1:

| | Test | Standard | Center | Setup time | Hold time |
|---|---|---|---|---|---|
| Scan item | result | requirement | setting | margin | margin |
| 250k CMD read | Pass | 8 phases | Phase 8 | 7 phases | 7 phases |
| 250k CMD write | Pass | 2 phases | Phase 18 | 17 phases | 13 phases |
| 25M read | Pass | 8 phases | Phase 8 | 7 phases | 7 phases |
| 25M write | Pass | 6 phases | Phase 18 | 15 phases | 12 phases |
| 50M CMD read | Pass | 8 phases | Phase 8 | 7 phases | 7 phases |
| 50M CMD write | Pass | 10 phases | Phase 18 | 17 phases | 13 phases |
| 50M data write | Pass | 10 phases | Phase 18 | 13 phases | 12 phases |
| HS200 | Pass | 14 phases | Phase 13 | 9 phases | 13 phases |
| data write | | | | | |
| HS200 | Pass | 14 phases | Phase 18 | 12 phases | 13 phases |
| CMD write | | | | | |
| H5400 write | Pass | 7 phases | Phase 10 | 4 phases | 3 phases |
| H5400 read | Pass | 7 phases | Phase 12 | 6 phases | 5 phases |

In some embodiments, a predetermined memory standard may be (but not limited to) JEDEC (Joint Electron Device Engineering Council) memory standard (e.g., JESD84-B51 or its successor version). In some embodiments, the host circuit 140 may be configured to remove at least one second phase from the at least one first phase according to the predetermined memory standard. In some embodiments, the host circuit 140 may select a specific phase from the at least one first phase according to the predetermined memory standard, in order to generate the lookup table LT.

For example, according to the predetermined memory standard and/or input from a user, the host circuit 140 may remove the at least one second phase (e.g., phase 0 and phase 16) from phases 0-16. The at least one second phase may be a timing that is not recommended in the predetermined memory standard (also referred to as “dead zone”), or may be a timing that is tested to be failure (or actual operation failure) in other embedded memory circuits. As a result, the host circuit 140 may obtain that the embedded memory circuit 120 may select a specific phase (e.g., phase 8 shown in the center setting of the above table) from phases 1-15, in order to generate the lookup table LT. In some embodiments, the specific phase may be (but not limited to) a central phase in the at least one phase.

In some embodiments, the center setting may be adjusted according to practical applications and/or other design consideration, and thus the center setting of the above table is not limited to the central phase in the at least one first phase. In some embodiments, for certain instructions (which may be, but not limited to, a read instruction corresponding a frequency of 200 MHz), the embedded memory circuit 120 may perform an auto-tune mechanism to select the proper phase instead of utilizing the corresponding phase according to the center setting of the lookup table LT.

In some embodiments, the host circuit 140 is further configured to determine a corresponding relation between a setup time of a specific signal generated by the embedded memory circuit 120 in response to each instruction and phases (e.g., phases 0-31) according to the predetermined memory standard, in order to generate the lookup table LT. Similarly, in some embodiments, the host circuit 140 is configured to determine a corresponding relation between a hold time of a specific signal generated by the embedded memory circuit 120 in response to each instruction and phases 0-31 according to the predetermined memory standard, in order to generate the lookup table LT. In some embodiments, the setup time is an interval for the specific signal keep being fixed before a transiting edge of the clock signal having the corresponding phase occurs, and the hold time is an interval for the specific signal keep being fixed after a transiting edge of the clock signal having the corresponding phase occurs.

Taking the write instruction performed in the HS400 mode as an example, the specific signal may be a data signal that is written by the embedded memory circuit 120 in response to this instruction. As the clock frequency in the HS400 mode is 200 MHz (i.e., data rate is up to 400 MB/s), it can be known that an interval between two successive phases in phases 0-31 is about 0.156 nanosecond (ns) according to the period of the clock signal (i.e., 1/200M). According to requirements of the setup time and the hold time in the predetermined memory standard (e.g., at least 0.4 ns), the host circuit 140 may obtain that the sum of the setup time and the hold time is at least required to be the same as a total time of 7 intervals in 7 phases (i.e., the standard requirement in table 1). Furthermore, according to test results of FIG. 4, the embedded memory circuit 120 may utilize the testing clock signal CLK having a phase in phases 6-13 to execute this write instruction. Accordingly, the host circuit 140 may select a central phase 10 in phases 6-13 (i.e., the center setting in table 1) to be a specific phase for executing this write instruction, such that a margin for the setup time can be the same as a margin for the hold time as much as possible. For example, the margin for the setup time is a total time of intervals in phases 6-9 (i.e., 4 phases in table 1), and the margin for the hold time is a total time of intervals in phases 11-31 (i.e., 3 phases in table 1). As a result, in subsequent applications, the embedded memory circuit 120 may utilize the clock signal having phase 10 to execute this write instruction.

The above examples are described with reference to testing results of a single the embedded memory circuit 120. It is understood that, in some embodiments, the host circuit 140 may generate the lookup table LT according to an intersection of test results of multiple embedded memory circuits 120. As a result, the timing settings stored in the lookup table LT are able to be applied to different memories of different manufacturers.

The above operations of the timing scan testing method 200 (or the memory testing method 300) can be understood with reference to the above embodiments, and thus the repetitious descriptions are not further given. The above description of the timing scan testing method 200 (or the memory testing method 300) includes exemplary operations, but the operations are not necessarily performed in the order described above. Operations of the timing scan testing method 200 (or the memory testing method 300) may be added, replaced, changed order, and/or eliminated as appropriate, or the operations are able to be executed simultaneously or partially simultaneously as appropriate, in accordance with the spirit and scope of various embodiments of the present disclosure.

As described above, the embedded memory system and the memory testing method in some embodiments of the present disclosure are able to utilize a kernel operating in an embedded memory circuit or a program of an operating system to run a timing scan test on the embedded memory circuit, in order to determine proper phases for actual operations of the embedded memory circuit. As a result, in subsequent applications, the embedded memory circuit is able to operate with proper phase(s).

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. An embedded memory system, comprising:
an embedded memory circuit configured to store a lookup table; and
a host circuit configured to utilize a testing clock signal having a plurality of phases and a plurality of instructions in a program of the embedded memory circuit to run a test on the embedded memory circuit, and record a corresponding relation between each of the plurality of instructions and the plurality of phases, in order to generate the lookup table.

2. The embedded memory system of claim 1, wherein the program is a boot loader, and the boot loader is a kernel that operates with the embedded memory circuit or is a program executed during a boot process of an operating system.

3. The embedded memory system of claim 1, wherein the plurality of instructions comprise a plurality of read instructions or a plurality of write instructions that are performed with different clock frequencies.

4. The embedded memory system of claim 1, wherein the embedded memory circuit is configured to sequentially utilize the plurality of phases to execute a first instruction in the plurality of instructions to generate a test result, and the host circuit is configured to determine whether the embedded memory circuit utilizes at least one first phase in the plurality of phases to execute the first instruction properly according to the test result.

5. The embedded memory system of claim 4, wherein the host circuit is further configured to select a specific phase from the at least one first phase according to a predetermined memory standard, in order to generate the lookup table.

6. The embedded memory system of claim 5, wherein the host circuit is further configured to remove at least one second phase from the at least one first phase according to the predetermined memory standard.

7. The embedded memory system of claim 5, wherein the host circuit is further configured to determine a corresponding relation between a setup time of a signal generated by the embedded memory circuit in response to the first instruction and the plurality of phases according to the predetermined memory standard, in order to generate the lookup table.

8. The embedded memory system of claim 5, wherein the host circuit is further configured to determine a corresponding relation between a hold time of a signal generated by the embedded memory circuit in response to the first instruction and the plurality of phases according to the predetermined memory standard, in order to generate the lookup table.

9. The embedded memory system of claim 5, wherein the specific phase is a central phase in the at least one first phase.

10. The embedded memory system of claim 5, wherein the predetermined memory standard is a JEDEC (Joint Electron Device Engineering Council) memory standard.

11. A memory testing method, comprising:
utilizing a testing clock signal having a plurality of phases and a plurality of instructions in a program to run a test on an embedded memory circuit; and
recording a corresponding relation between each of the plurality of instructions and the plurality of phases, in order to generate a lookup table,
wherein the embedded memory circuit is configured to select a specific phase, which corresponds to a first instruction in the plurality of instructions, in the plurality of phases according to the lookup table, in order to execute the first instruction.

12. The memory testing method of claim 11, wherein the program is a boot loader, and the boot loader is a kernel that operates with the embedded memory circuit or is a program executed during a boot process of an operating system.

13. The memory testing method of claim 11, wherein the plurality of instructions comprise a plurality of read instructions or a plurality of write instructions that are performed with different clock frequencies.

14. The memory testing method of claim 11, wherein utilizing the testing clock signal having the plurality of phases and the plurality of instructions in the program to run the test on the embedded memory circuit comprises:
determining whether the embedded memory circuit utilizes at least one first phase in the plurality of phases to execute the first instruction properly according to a test result,
wherein the embedded memory circuit is configured to sequentially utilize the plurality of phases to execute the first instruction to generate the test result.

15. The memory testing method of claim 14, wherein recording the corresponding relation between each of the plurality of instructions and the plurality of phases, in order to generate the lookup table comprises:
selecting the specific phase from the at least one first phase according to a predetermined memory standard, in order to generate the lookup table.

16. The memory testing method of claim 15, wherein recording the corresponding relation between each of the plurality of instructions and the plurality of phases, in order to generate the lookup table comprises:
removing at least one second phase from the at least one first phase according to the predetermined memory standard.

17. The memory testing method of claim 15, wherein recording the corresponding relation between each of the plurality of instructions and the plurality of phases, in order to generate the lookup table comprises:
determining a corresponding relation between a setup time of a signal generated by the embedded memory circuit in response to the first instruction and the plurality of phases according to the predetermined memory standard, in order to generate the lookup table.

18. The memory testing method of claim 15, wherein recording the corresponding relation between each of the plurality of instructions and the plurality of phases, in order to generate the lookup table comprises:
determining a corresponding relation between a hold time of a signal generated by the embedded memory circuit in response to the first instruction and the plurality of phases according to the predetermined memory standard, in order to generate the lookup table.

19. The memory testing method of claim 15, wherein the predetermined memory standard is a JEDEC (Joint Electron Device Engineering Council) memory standard.

20. The memory testing method of claim 15, wherein the specific phase is a central phase in the at least one first phase.
